(19) United States
(12) Patent Application Publication
(10) Pub. No.: US 2025/0343029 A1
(43) Pub. Date: Nov. 6, 2025

(54) SUBSTRATE PROCESSING APPARATUS, GAS SUPPLY STRUCTURE, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Yusaku OKAJIMA, Toyama-shi (JP); Hiroki HATTA, Toyama-shi (JP); Mika URUSHIHARA, Toyama-shi (JP)

(73) Assignee: Kokusai Electric Corporation, Tokyo (JP)

(21) Appl. No.: 19/268,246

(22) Filed: Jul. 14, 2025

Related U.S. Application Data
(63) Continuation-in-part of application No. PCT/JP2023/000873, filed on Jan. 13, 2023.

(51) Int. Cl. H01J 37/32

(52) U.S. Cl. CPC H01J 37/3244; H01J 37/32715; H01J 2237/332

(57) ABSTRACT

Provided is a substrate processing apparatus including: a processing chamber that accommodates a substrate holder holding a plurality of substrates; a plurality of gas suppliers that are disposed in a direction parallel to a surface of the substrate, extend from an outside to an inside of the processing chamber, and each include a first gas introduction portion that introduces a first gas, a second gas introduction portion that introduces a second gas, and a mixing portion that mixes the first gas with the second gas; and an accommodating portion that is disposed to extend in the direction parallel to the surface of the substrate on a lateral side of the processing chamber and accommodates the plurality of gas suppliers.

### CROSS-REFERENCE TO RELATED APPLICATION

This application is a Bypass Continuation Application of PCT International Application No. PCT/JP2023/000873, filed on Jan. 13, 2023, the entire contents of which are incorporated herein by reference.

### BACKGROUND

### Field

The present disclosure relates to a substrate processing apparatus, a gas supply structure, a method of processing a substrate, a method of manufacturing a semiconductor device, and a recording medium.

### Description of the Related Art

As one step of the manufacturing process of the semiconductor device, for example, a process of forming a film on the surface of the substrate accommodated in the processing container by supplying a mixed gas obtained by mixing a plurality of gases may be performed.

### SUMMARY

However, when the mixed gas is supplied, the temperature of the mixed gas varies between the substrates accommodated in the processing container, and the film forming processing between the substrates may not be uniformly performed.

The present disclosure provides a technique enabling uniform film formation processing between substrates.

According to an aspect of the present disclosure, provided is a technique including:
a processing chamber that accommodates a substrate holder holding a plurality of substrates;
a plurality of gas suppliers that are disposed in a direction parallel to a surface of the substrate, extend from an outside to an inside of the processing chamber, and each include a first gas introduction portion that introduces a first gas, a second gas introduction portion that introduces a second gas, and a mixing portion that mixes the first gas with the second gas; and
an accommodating portion that is disposed to extend in the direction parallel to the surface of the substrate on a lateral side of the processing chamber and accommodates the plurality of gas suppliers.

### BRIEF DESCRIPTION OF THE DRAWINGS

FIG. 1 is an explanatory diagram illustrating a schematic configuration example of a substrate processing apparatus according to an embodiment of the present disclosure.

FIG. 2 is an explanatory diagram illustrating a schematic configuration example of a substrate processing apparatus according to an embodiment of the present disclosure.

FIG. 3 is an explanatory diagram illustrating a schematic configuration example of a substrate processing apparatus according to an embodiment of the present disclosure.

FIG. 4 is an explanatory diagram explaining a substrate support according to one aspect of the present disclosure.

FIGS. 5A to 5C are explanatory diagrams for explaining a gas supply system according to one aspect of the present disclosure.

FIG. 5A is an explanatory diagram for explaining a gas supply system of a third gas and a fourth gas, FIG. 5B is an explanatory diagram for explaining a gas supply system of a first gas, and FIG. 5C is an explanatory diagram for explaining a gas supply system of a second gas.

FIG. 6 is an explanatory diagram explaining a gas exhaust system according to one aspect of the present disclosure.

FIG. 7 is an explanatory diagram explaining a controller of the substrate processing apparatus according to one aspect of the present disclosure.

FIGS. 8A to 8C are explanatory views illustrating a schematic configuration example of a gas nozzle according to one aspect of the present disclosure. FIG. 8A is a plan view of the gas nozzle, and FIGS. 8B and 8C are front views of the gas nozzle.

### DETAILED DESCRIPTION

### Embodiment of Present Disclosure

Hereinafter, embodiments of the present aspect will be described with reference to the drawings. In all the drawings, the same or corresponding constituents are denoted with the same or corresponding reference signs, and thus duplicate descriptions will be omitted. The drawings used in the following descriptions are all schematic, and dimensional relationships of elements, ratios of the elements, and the like in the drawings do not necessarily coincide with actual ones. In addition, the dimensional relationship between each constituent element, the ratio between each constituent element, and the like do not necessarily coincide among a plurality of drawings.

### (1) Configuration of Substrate Processing Apparatus

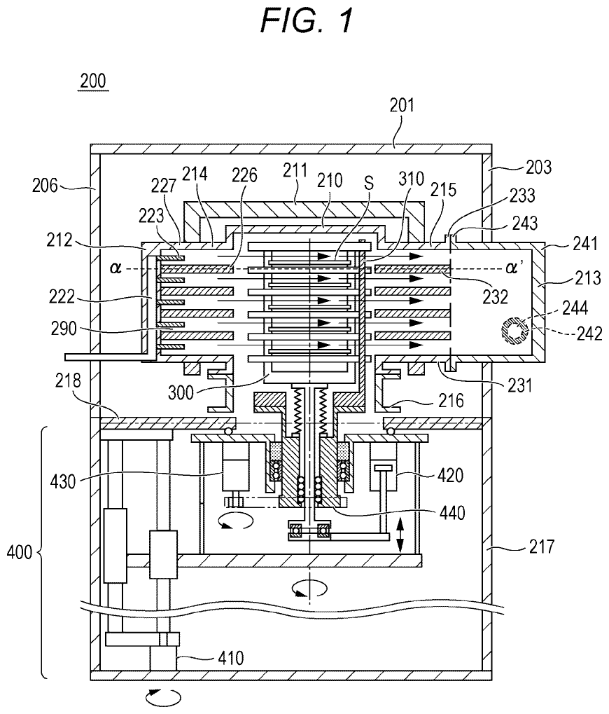

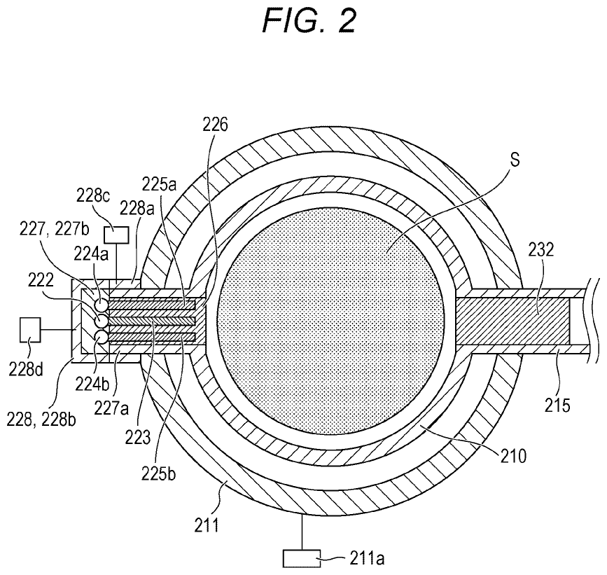

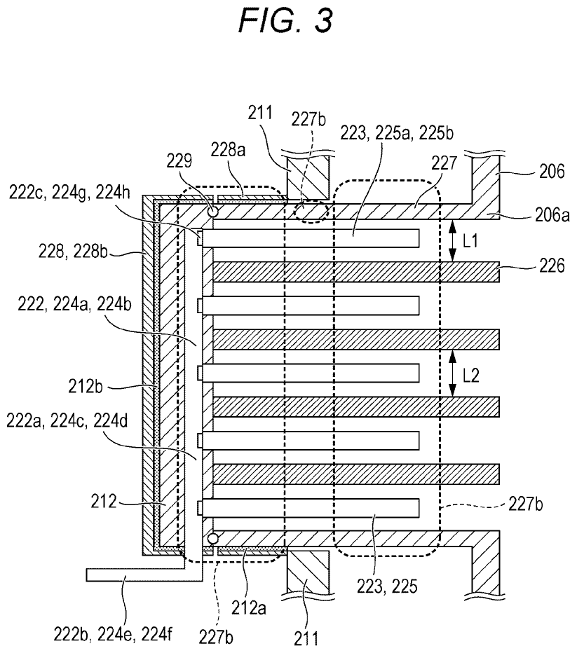

A schematic configuration of a substrate processing apparatus according to one aspect of the present disclosure will be described with reference to FIGS. 1 to 8. FIG. 1 is a side sectional view of a substrate processing apparatus 200, and FIG. 2 is a sectional view taken along a line x-x′ in FIG. 1. Here, for convenience of explanation, a nozzle 225a as a first gas introduction portion, a nozzle 225b as a second gas introduction portion, and a nozzle 223 as a third gas introduction portion are added. As illustrated in FIG. 2, the nozzle 223 and the nozzles 225a, 225b are arranged side by side. Here, in the horizontal direction, the nozzle 223 is disposed at the center of the housing 227, and the nozzles 225a, 225b are disposed on both sides thereof. Hereinafter, the nozzles 225a, 225b may be collectively referred to simply as a nozzle 225. FIG. 3 is an explanatory diagram explaining a relationship between a housing 227, a heater 211, and a distributor. For convenience of explanation, a distributor 222 and the nozzle 223 are illustrated, and distributors 224a, 224b and the nozzles 225a, 225b are omitted here.

Next, specific details will be described. The substrate processing apparatus 200 includes a housing 201, and the housing 201 includes a reaction tube storage chamber 206 and a transfer chamber 217. The reaction tube storage chamber 206 is disposed above the transfer chamber 217.

The reaction tube storage chamber 206 includes a reaction tube 210 in a cylindrical shape extending in the vertical direction, the heater 211 serving as a heater (furnace body) installed on the outer periphery of the reaction tube 210, a gas supply system 212 serving as a gas supply structure, and a gas exhaust system 213 serving as a gas exhaust structure. Here, the reaction tube 210 is also referred to as a processing chamber, and a space inside the reaction tube 210 is also referred to as a processing space. The reaction tube 210 can store a substrate holder 300 to be described later.

In the heater 211, a resistance heater is provided on an inner surface facing the side of the reaction tube 210, and a heat insulator is provided to surround the resistance heater. Thus, the outer side of the heater 211, that is, the side not facing the reaction tube 210 is configured to have less thermal influence. A heater controller 211a is electrically coupled to the resistance heater of the heater 211. With the heater controller 211a controlled, on/off of the heater 211 and a heating temperature can be controlled. The heater 211 is capable of heating a gas to be described later to a temperature at which the gas can be thermally decomposed. The heater 211 is also referred to as a processing chamber heater or a first heater.

The reaction tube 210, an upstream side gas guide 214, and a downstream side gas guide 215 are provided inside the reaction tube storage chamber 206. The gas supplier may include the upstream side gas guide 214. In addition, the gas exhauster may include the downstream side gas guide 215.

The gas supply system 212 is provided upstream in the gas flow direction of the reaction tube 210, and the gas is supplied from the gas supply system 212 to the reaction tube 210. The gas exhaust system 213 is provided downstream in the gas flow direction of the reaction tube 210, and the gas inside the reaction tube 210 is discharged from the gas exhaust system 213.

The upstream side gas guide 214 that guides the flow of the gas supplied from the gas supply system 212 is provided between the reaction tube 210 and the gas supply system 212. That is, the gas supply system 212 is adjacent to the upstream side gas guide 214. The downstream side gas guide 215 that guides the flow of the gas discharged from the reaction tube 210 is provided between the reaction tube 210 and the gas exhaust system 213. The reaction tube 210 has a lower end supported by a manifold 216.

The reaction tube 210, the upstream side gas guide 214, and the downstream side gas guide 215 are provided as a continuous structure, and are formed of a material such as quartz or Sic, for example. These include a heat-permeable member that allows heat radiated from the heater 211 to pass through. The heat from the heater 211 causes a substrate S and the gas to be heated.

A housing constituting the gas supply system 212 includes metal, and the housing 227, which is a part of the upstream side gas guide 214, includes quartz or the like. The gas supply system 212 and the housing 227 are separable from each other, and are fixed with an O-ring 229 interposed therebetween when being fixed. The housing 227 is coupled to a connection portion 206a on the lateral side of the reaction tube 210.

The housing 227 extends in a direction different from the reaction tube 210 when viewed from the side of the reaction tube 210, and is coupled to the gas supply system 212 to be described later. The heater 211 and the housing 227 are adjacent to each other at an adjacent portion 227b between the reaction tube 210 and the gas supply system 212. The adjacent portions are referred to as the adjacent portion 227b.

The gas supply system 212 is provided on the rear side of the adjacent portion 227b when viewed from the reaction tube 210. The gas supply system 212 includes the distributor 224a communicable with a gas supply pipe 261, the distributor 224b communicable with the gas supply pipe 271, and the distributor 222 communicable with the gas supply pipe 251 to be described later. A plurality of nozzles 223 are provided on a downstream side of the distributor 222, a plurality of nozzles 225a are provided downstream of the distributor 224a, and a plurality of nozzles 225b are provided downstream of the distributor 224b. The plurality of nozzles is disposed in the vertical direction. The distributor 222 and the nozzles 223 are illustrated in FIG. 1. Next to the gas supply system 212, an accommodating portion 290 extending in a direction parallel to the surface of the substrate S on the lateral side of the reaction tube 210 and accommodating a gas nozzle 220 as a gas supplier (gas supply structure) to be described later is disposed.

An ejection port to be described later is provided on the distal end side (side opposite to the side in communication with the distributors 222, 224a and 224b) of each of the nozzles 223, 225a, and 225b. Each of the nozzles 223, 225a, and 225b supplies gas into the processing space through the ejection port on the distal end side. Each of the nozzles 223, 225a, and 225b and the ejection port in communication with those nozzles are provided in a gas nozzle 220 to be described later.

As described later, since the distributor 222 enables distribution of a source gas, it is also referred to as a source gas distributor. Since the nozzles 223 supply the source gas, they are also referred to as source gas supply nozzles.

In addition, since the distributors 224a, 224b enable distribution of a reactant gas, it is also referred to as a reactant gas distributor. Since the nozzles 225a, 225b supply the reactant gas, they are also referred to as reactant gas supply nozzles.

As described later, the gas supply pipe 251, the gas supply pipe 261, and the gas supply pipe 271 supply different types of gases.

As illustrated in FIG. 3, the distributor 222 is provided with a plurality of blow-off holes 222c. The blow-off holes 222c are provided not to overlap each other in the vertical direction. The plurality of nozzles 223 is coupled to the blow-off holes 222c provided in the distributor 222 such that the blow-off holes 222c communicates with the inside of the respective nozzles 223. The nozzles 223 are disposed in the vertical direction between division plates 226 to be described later or between the housing 227 and the division plate 226.

The distributor 222 includes a distribution structure 222a coupled to the nozzles 223, and an introduction pipe 222b. The introduction pipe 222b communicates with the gas supply pipe 251 of a gas supplier 250 to be described later.

The distribution structure 222a is disposed on the rear side of the heater 211 when viewed from the reaction tube 210. Thus, the distribution structure 222a is disposed at a position not easily affected by the heater 211.

An upstream side heater 228 capable of heating at a temperature lower than that of the heater 211 is provided around the gas supply system 212 and the housing 227. The upstream side heater 228 includes two heaters 228a and 228b. Specifically, the upstream side heater 228a is provided around a surface that is a surface of the housing 227 and a surface between the gas supply system 212 and the adjacent portion 227b. In addition, the upstream side heater 228b is provided around the gas supply system 212. The upstream side heater 228 is also referred to as an upstream side heater or a second heater.

Here, a low temperature indicates a temperature at which the gas supplied into the distributor 222 is not re-liquefied, for example, and is also a temperature at which a low decomposition state of the gas is maintained.

Similarly to the distributor 222, the distributor 224a includes a distribution structure 224c coupled to the nozzles 225a, and an introduction pipe 224e. The introduction pipe 224e communicates with the gas supply pipe 261 of a gas supplier 260 to be described later. The distributor 224a and the nozzle 225a are coupled to each other such that holes 224g provided in the distributor 224a communicate with the inside of the nozzle 225a. Similarly to the distributor 222, the distributor 224b also includes a distribution structure 224d coupled to the nozzle 225b, and an introduction pipe 224f. The introduction pipe 224f communicates with the gas supply pipe 271 of a gas supplier 270 to be described later. The distributor 224b and the nozzle 225b are coupled to each other such that holes 224h provided in the distributor 224b communicate with the inside of the nozzle 225b. The nozzles 225a, 225b are disposed at line-symmetric positions around the nozzle 223, for example.

As described above, with the distributor and the nozzles provided for each gas to be supplied, the gas supplied from each of the gas supply pipes can be prevented from being mixed in each of the gas distributors.

At least a part of the configuration of the upstream side heater 228a is disposed in parallel with the extending direction of the nozzle 223 and the nozzles 225a, 225b. At least a part of the configuration of the upstream side heater 228b is provided along the arrangement direction of the distributor 222. With this arrangement, the low temperature can be maintained even in the nozzles and in the distributors.

A heater controller 228 is electrically coupled to the upstream side heater 228. Specifically, a heater controller 228c is coupled to the upstream side heater 228a, and a heater controller 228d is coupled to the upstream side heater 228b. With the heater controllers 228c and 228d controlled, on/off of the heater 228 and a heating temperature can be controlled. Although the two heater controllers 228c and 228d have been described here, it is not limited thereto, and one heater controller or three or more heater controllers may be used as long as desired temperature control is enabled. The upstream side heater 228 is also referred to as a second heater.

The upstream side heater 228 is detachable, and can be detached in advance from the gas supply system 212 and the housing 227 at the time of separating the gas supply system 212 and the housing 227 from each other. In addition, it may be fixed to each part, and at the time of separating the gas supply system 212 and the housing 227 from each other, the gas supply system 212 and the housing 227 may be separated from each other while it is fixed to the gas supply system 212 or the housing 227.

A metal cover 212a made of, for example, metal, which serves as a cover, may be provided between the upstream side heater 228a and the housing 227. With the metal cover 212a provided, heat generated by the upstream side heater 228a can be efficiently supplied into the housing 227. In particular, while there is concern about heat dissipation in the housing 227 due to its material of quartz, the heat dissipation can be suppressed by the metal cover 212a being provided. Accordingly, it is not needed to perform excessive heating, whereby power supply to the heater 228 can be reduced.

A metal cover 212b may be provided between the upstream side heater 228b and the housing constituting the gas supply system 212. With the metal cover 212b provided, heat generated by the upstream side heater 228b can be efficiently supplied to the distributor. Accordingly, the power supply to the upstream side heater 228 can be reduced.

The upstream side gas guide 214 includes the housing 227 and the division plates 226. A part of the division plate 226 serving as a partition facing the substrate S is extended in the horizontal direction to be larger than at least the diameter of the substrate S. The horizontal direction mentioned here indicates a side wall direction of the housing 227. A plurality of the division plates 226 is disposed in the vertical direction in the housing 227. The division plate 226 is fixed to the side wall of the housing 227, and is configured such that the gas does not move to a lower or upper adjacent region beyond the division plate 226. With such a configuration in which the gas does not move beyond, a gas flow to be described later can be reliably formed.

The division plates 226 have a continuous structure without a hole. Each of the division plates 226 is provided at a position corresponding to the substrate S. The nozzle 223 and the nozzles 225a, 225b are provided between the division plates 226 and between the division plate 226 and the housing 227. That is, the nozzle 223 and the nozzles 225a, 225b are provided at least for each division plate 226.

The respective distances between the division plates 226 and the nozzles 223 disposed above the division plates 226 are desirably the same. That is, arrangement is made in which the respective spaces have the same heights between the nozzle 223 and the division plate 226 or the housing 227 disposed below the nozzle 223. With this arrangement, the distance from the tip of the nozzle 223 to the division plate 226 can be made the same, whereby a degree of decomposition on the substrate S can be uniformed among the plurality of substrates.

The gas flow of the gas discharged from the nozzle 223 and the nozzle 225 is guided by the division plate 226, and is supplied to the surface of the substrate S. Since the division plate 226 extends in the horizontal direction and has a continuous structure without a hole, the mainstream of the gas is suppressed to move in the vertical direction, and moves in the horizontal direction. Thus, the pressure loss of the gas reaching each substrate S can be uniformed in the vertical direction.

In the present aspect, the diameter of the blow-off hole 222c provided in the distributor 222 is smaller than the distance between the division plates 226 or the distance between the housing 227 and the division plate 226.

The downstream side gas guide 215 is configured such that, in a state where the substrates S are supported by the substrate holder 300, the ceiling is higher than the substrate S disposed at the uppermost position and the bottom is lower than the substrate S disposed at the lowermost position of the substrate holder 300.

The downstream side gas guide 215 includes a housing 231 and a division plate 232. A portion of the division plate 232 facing the substrate S is extended in the horizontal direction to be larger than at least the diameter of the substrate S. The horizontal direction mentioned here indicates a side wall direction of the housing 231. Furthermore, a plurality of the division plates 232 is disposed in the vertical direction. The division plate 232 is fixed to the side wall of the housing 231, and is configured such that the gas does not move to a lower or upper adjacent region beyond the division plate 232. With such a configuration in which the gas does not move beyond, a gas flow to be described later can be reliably formed. A flange 233 is provided on the side of the housing 231 in contact with the gas exhaust system 213.

The division plates 232 have a continuous structure without a hole. Each of the division plates 232 is provided at a position corresponding to the substrate S, the position corresponding to the division plate 226. The division plate 226 and the division plate 232 corresponding to each other are desirably equivalent in height. Furthermore, the height of the substrate S and the heights of the division plate 226 and the division plate 232 are desirably aligned at the time of processing the substrate S. With such a structure, the gas supplied from each nozzle forms a flow passing on the division plate 226, the substrate S, and the division plate 232 as indicated by the arrow in the drawing. At this time, the division plate 232 extends in the horizontal direction and has a continuous structure without a hole. With such a structure, the pressure loss of the gas discharged from each substrate S can be uniformed. Therefore, the gas that passes on each substrate S flows horizontally to the gas exhaust system 213 without flowing vertically.

With the division plate 226 and the division plate 232 provided, the pressure loss in the vertical direction can be uniformed on the upstream side and the downstream side of each substrate S, whereby the horizontal gas flow in which the flow in the vertical direction is suppressed can be reliably formed over the division plate 226, the substrate S, and the division plate 232.

The gas exhaust system 213 is provided downstream of the downstream side gas guide 215. The gas exhaust system 213 mainly includes a housing 241 and a gas exhaust pipe connector 242. A flange 243 is provided on the side of the downstream side gas guide 215 of the housing 241.

The gas exhaust system 213 communicates with a space of the downstream side gas guide 215. The housing 231 and the housing 241 have a structure continuous in height. The ceiling of the housing 231 has a height equivalent to that of the ceiling of the housing 241, and the bottom of the housing 231 has a height equivalent to that of the bottom of the housing 241.

The gas having passed through the downstream side gas guide 215 is exhausted from an exhaust hole 244. At this time, since the gas exhaust structure does not include a configuration like a division plate, a gas flow including the vertical direction is formed toward the gas exhaust hole.

The transfer chamber 217 is disposed below the reaction tube 210 with the manifold 216 interposed therebetween. In the transfer chamber 217, a vacuum transfer robot (not illustrated) places (mounts) the substrate S on the substrate holder (which may be simply referred to as a boat hereinafter) 300, or the vacuum transfer robot takes out the substrate S from the substrate holder 300.

The transfer chamber 217 can store therein the substrate holder 300, a partition plate support 310, and an up-down direction drive mechanism 400 constituting a first driver that drives the substrate holder 300 and the partition plate support 310 (which are collectively referred to as a substrate holder) in the up-down direction and in the rotational direction. FIG. 1 illustrates a state in which the substrate holder 300 is raised by the up-down direction drive mechanism 400 and is stored in the reaction tube.

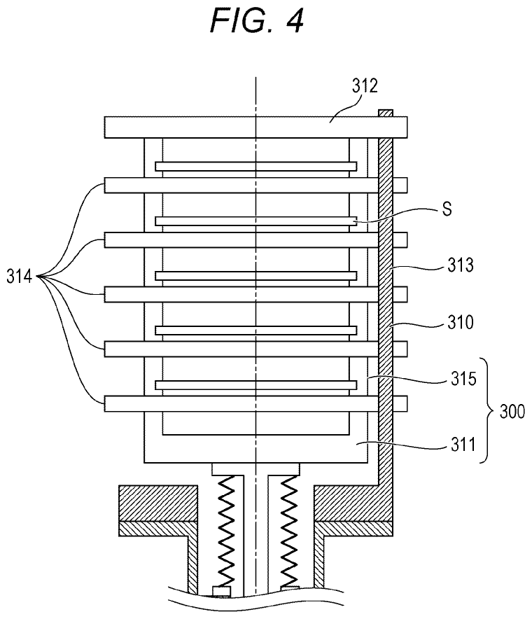

Next, details of a substrate support will be described with reference to FIGS. 1 and 4.

The substrate holder includes at least the substrate holder 300, and replaces, using the vacuum transfer robot, the substrate S via a substrate loading port 149 inside the transfer chamber 217, and transfers the replaced substrate S to the inside of the reaction tube 210 to form a thin film on the surface of the substrate S. The substrate support may include the partition plate support 310.

In the partition plate support 310, a plurality of partition plates 314 having a disk shape is fixed at a predetermined pitch to a column 313 supported between a base 311 and a top plate 312. The substrate holder 300 is configured such that a plurality of support rods 315 is supported by the base 311, and the plurality of substrates S is supported by the plurality of support rods 315 at predetermined intervals.

The plurality of substrates S is placed on the substrate holder 300 at the predetermined intervals by the plurality of support rods 315 supported by the base 311. The plurality of substrates S supported by the support rods 315 is partitioned by the partition plates 314 having the disk shape fixed (supported) to the column 313 supported by the partition e support 310 at the predetermined intervals. Here, the partition plate 314 is disposed above or below the substrate S, or both.

The predetermined interval between the plurality of substrates S placed on the substrate holder 300 is the same as the vertical interval between the partition plates 314 fixed to the partition plate support 310. The diameter of the partition plate 314 is larger than the diameter of the substrate S.

The boat 300 supports the plurality of, for example, five substrates S in multiple stages in the vertical direction with the plurality of support rods 315. The base 311 and the plurality of support rods 315 are formed of a material such as quartz or SiC, for example. Although an exemplary case where the five substrates

S are supported by the boat 300 is described here, it is not limited thereto. For example, the boat 300 may be capable of supporting approximately 5 to 50 substrates S. The partition plate 314 of the partition plate support 310 is also referred to as a separator.

The partition plate support 310 and the substrate holder 300 are driven by the up-down direction drive mechanism 400 in the up-down direction between the reaction tube 210 and the transfer chamber 217 and in the rotational direction around the center of the substrate S supported by the substrate holder 300.

The up-down direction drive mechanism 400 constituting the first driver includes an upward/downward drive motor 410 and a rotation drive motor 430 serving as drive sources, and a boat elevator 420 including a linear actuator serving as a substrate holder lift mechanism that drives the substrate holder 300 in the up-down direction.

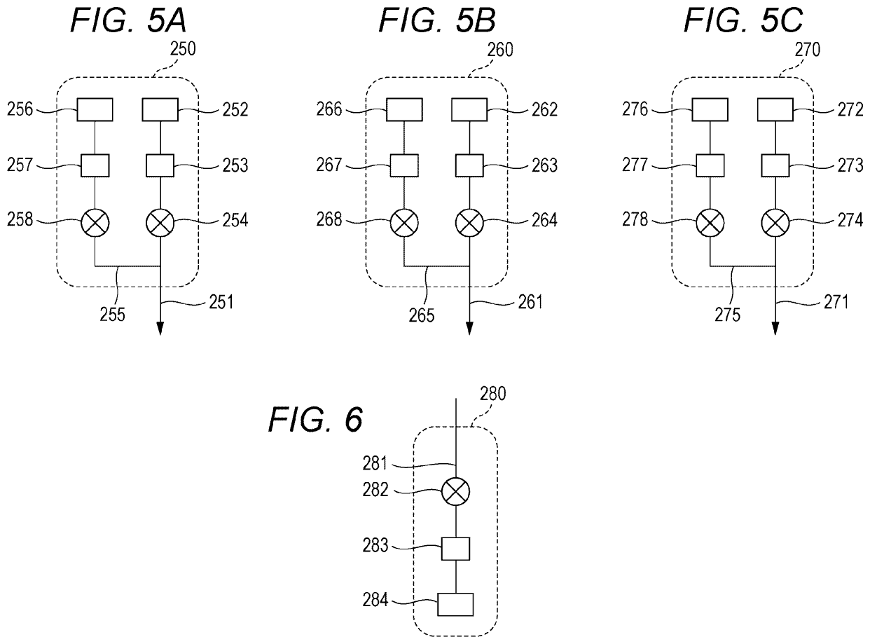

Next, details of the gas supply system will be described with reference to FIGS. 5A to 5C.

As illustrated in FIG. 5A, the gas supply pipe 251 is provided with a fourth gas source 252, a mass flow controller (MFC) 253, which is a flow rate controller, and a valve 254, which is an on-off valve, in this order from the upstream direction. The fourth gas source 252 is, for example, a gas source of a fourth gas which is a source gas.

The fourth gas supply system 250 (also referred to as a “source gas supply system”) mainly includes the gas supply pipe 251, the MFC 253, and the valve 254. The gas supply pipe 251 is coupled to the introduction pipe 222b of the distributor 222.

A gas supply pipe 255 is coupled to the downstream side of the valve 254 of the supply pipe 251. The gas supply pipe 255 is provided with an inert gas source 256, an MFC 257, and a valve 258, which is an on-off valve, in this order from the upstream direction.

A third inert gas supply system mainly includes the gas supply pipe 255, the MFC 257, and the valve 258. The inert gas supplied from the inert gas source 256 acts as a purge gas for purging the gas remaining in the reaction tube 210 in the substrate processing step. The third inert gas supply system may be added to the fourth gas supply system 250.

As illustrated in FIG. 5B, the gas supply pipe 261 is provided with a first gas source 262, an MFC 263, which is a flow rate controller, and a valve 264, which is an on-off valve, in this order from the upstream direction. The gas supply pipe 261 is coupled to the introduction pipe 224e of the distributor 224a. The first gas source 262 is, for example, a gas source of a first gas which is a reactant gas.

The gas supply pipe 261, the MFC 263, and the valve 264 mainly constitute the first gas supply system 260.

A gas supply pipe 265 is coupled to the downstream side of the valve 264 of the supply pipe 261. The gas supply pipe 265 is provided with an inert gas source 266, an MFC 267, and a valve 268, which is an on-off valve, in this order from the upstream direction. An inert gas is supplied from the inert gas source 266.

A first inert gas supply system mainly includes the gas supply pipe 265, the MFC 267, and the valve 268. The inert gas supplied from the inert gas source 266 acts as a purge gas for purging the gas remaining in the reaction tube 210 in a substrate processing step. The first inert gas supply system may be added to the first gas supply system 260.

As illustrated in FIG. 5C, the gas supply pipe 271 is provided with a second gas source 272, an MFC 273, which is a flow rate controller, and a valve 274, which is an on-off valve, in this order from the upstream direction. The gas supply pipe 271 is coupled to the introduction pipe 224f of the distributor 224b.

The second gas source 272 is, for example, a gas source of a second gas which is a reactant gas.

The gas supply pipe 271, the MFC 273, and the valve 274 mainly constitute the second gas supply system 270.

A gas supply pipe 275 is coupled to the downstream side of the valve 274 of the supply pipe 271. The gas supply pipe 275 is provided with an inert gas source 276, an MFC 277, and a valve 278, which is an on-off valve, in this order from the upstream direction. An inert gas is supplied from the inert gas source 276.

A second inert gas supply system mainly includes the gas supply pipe 275, the MFC 277, and the valve 278. The inert gas supplied from the inert gas source 276 acts as a purge gas for purging the gas remaining in the reaction tube 210 in a substrate processing step. The second inert gas supply system may be added to the second gas supply system 270.

It is desirable not to dispose an inhibitor that inhibits the flow of the supplied gas between the nozzle 223, the nozzles 225a, 225b, and the substrate S. In particular, an inhibitor is not disposed between the substrate S and the nozzle 223 that supplies the gas containing the Si—Si bond.

If a configuration for inhibiting the gas flow is provided, it is considered that the gas hits against the inhibitor so that the partial pressure increases. Then, decomposition of the gas may be excessively promoted. In this case, the gas consumption amount increases, and the amount of the undecomposed gas supplied to the concave portion decreases, and as a result, a desired step coverage may not be achieved.

In view of the above, it is desirable not to provide an obstacle for the purpose of suppressing an increase to a pressure at which decomposition is promoted. Although it is described that no obstacle is provided here, a certain degree of obstacle may be present as long as the pressure does not increase to the pressure at which decomposition is promoted.

Next, an exhaust system will be described with reference to FIG. 6.

An exhaust system 280 that exhausts the atmosphere of the reaction tube 210 includes an exhaust pipe 281 communicating with the reaction tube 210, and is coupled to the housing 241 via the exhaust pipe connector 242.

As illustrated in FIG. 6, a vacuum pump 284 serving as a vacuum exhaust is coupled to the exhaust pipe 281 through a valve 282 serving as an on-off valve and an auto pressure controller (APC) valve 283 serving as a pressure regulator, whereby vacuum exhaust may be performed such that the pressure in the reaction tube 210 becomes a predetermined pressure (vacuum degree). The vacuum pump 284 may be included in the exhaust system. The exhaust system 280 is also referred to as a processing chamber exhaust system.

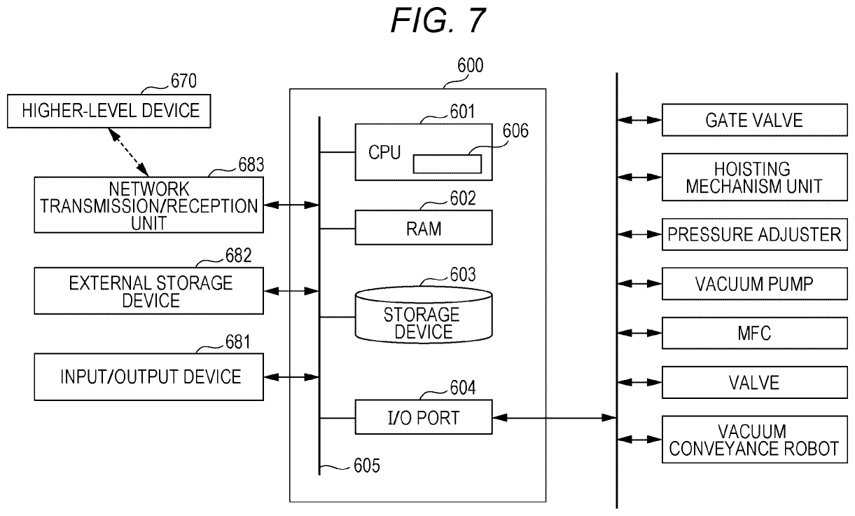

Next, a controller will be described with reference to FIG. 7. The substrate processing apparatus 200 includes a controller 600 that controls the operation of each constituent of the substrate processing apparatus 200.

FIG. 7 schematically illustrates the controller 600. The controller 600 serving as a controller is configured as a computer including a central processing unit (CPU) 601, a random access memory (RAM) 602, a memory 603 serving as a memory, and an I/O port 604. The RAM 602, the memory 603, and the I/O port 604 are capable of exchanging data with the CPU 601 via an internal bus 605. Transmission/reception of data in the substrate processing apparatus 200 is performed in accordance with an instruction from a transmission/reception instructor 606, which is one function of the CPU 601.

The controller 600 is provided with a network transceiver 683 connected to a host apparatus 670 via a network. The network transceiver 683 can receive, for example, information regarding the processing history and the processing schedule of the substrate S stored in a pod 111 from the host apparatus.

The memory 603 includes, for example, a flash memory, a hard disk drive (HDD), or the like. The memory 603 readably stores therein a control program for controlling the operation of the substrate processing apparatus, a process recipe describing procedures and conditions of the substrate processing, and the like.

The process recipe functions as a program for causing the controller 600 to perform each procedure in the substrate processing step to be described later to obtain a predetermined result. Hereinafter, the process recipe, the control program, and the like will also be collectively and simply referred to as a program. The term “program” in the present specification may include only the process recipe alone, only the control program alone, or both of them. The RAM 602 is configured as a memory area (work area) in which programs, data, and the like read by the CPU 601 are temporarily stored.

The I/O port 604 is coupled to each constituent of the substrate processing apparatus 200. The CPU 601 reads the control program from the memory 603 to execute it, and reads the process recipe from the memory 603 in response to an input of an operation command from an input/output device 681 or the like. Then, the CPU 601 may control the substrate processing apparatus 200 in accordance with the content of the read process recipe.

The CPU 601 includes the transmission/reception instructor 606. For example, by installing the program into a computer with use of an external memory (e.g., magnetic disk such as a hard disk, optical disk such as a digital versatile disc (DVD), magneto-optical disk such as a magneto-optical disc (MO), or semiconductor memory such as a universal serial bus (USB) memory) 682 in which the program described above is stored (recorded), it is possible to configure the controller 600 according to the present aspect. However, the means for supplying the program to the computer is not limited to the case of supplying the program through the external memory 682. For example, the program may be supplied using a communication means such as the Internet or a dedicated line, instead of through the external memory 682. Note that the memory 603 and the external memory 682 are configured as a computer-readable recording medium. Hereinafter, these will also be collectively and simply referred to as a recording medium. The term “recording medium” in the present specification may include only the memory 603 alone, only the external memory 682 alone, or both of them.

### (2) Configuration of Gas Supplier (Gas Nozzle)

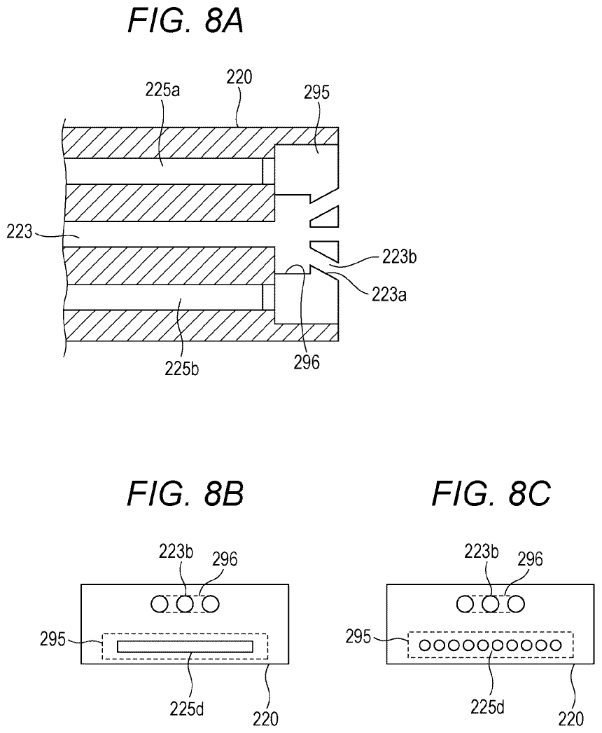

Next, a schematic configuration of the gas nozzle 220 as the gas supplier provided with each of the nozzles 223, 225a, and 225b and the like will be described with reference to FIGS. 8A to 8C. FIGS. 8A to 8C are explanatory views of the gas nozzle 220, in which FIG. 8A is a plan view of the gas nozzle 220 and FIGS. 8B and 8C are front views of the gas nozzle 220.

The gas nozzle 220 is disposed in a direction parallel to the surface of the substrate S, and is configured to extend from the outside to the inside of the reaction tube 210. The gas nozzle 220 is disposed in the vertical direction to correspond to each of the plurality of substrates S supported by the substrate holder 300. That is, the gas nozzle 220 is provided inside the accommodating portion 290 in multiple stages along the direction in which the substrates S are loaded, and are disposed at each position between the division plates 226 and between the division plate 226 and the housing 227 according to interval in the up-down direction of the plurality of substrates S. With such a configuration, the plurality of substrates S can be processed individually and at a time.

As illustrated in FIG. 8A, each of the plurality of gas nozzles 220 is provided with the nozzle 223 and the nozzles 225a, 225b arranged on both sides thereof to be positioned side by side.

As illustrated in FIG. 8A, each of the plurality of gas nozzles 220 is provided with a mixing portion 295 that mixes the first gas and the second gas introduced from each of the nozzles 225a, 225b on the tip side of the nozzles 223, 225a and 225b (on the side of the reaction tube 210 for processing the substrate S). The nozzles 225a, 225b communicate with a mixed gas ejection port 225d for ejecting a mixed gas of the first gas and the second gas via the mixing portion 295. As a result, the mixed gas of the first gas and the second gas mixed in the mixing portion 295 is ejected from the mixed gas ejection port 225d toward the substrate S supported by the substrate holder 300.

As shown in FIGS. 8A to 8C, a gas holding portion 296 through which the third gas and the fourth gas introduced from the nozzle 223 pass (are temporarily held) is provided above the mixing portion 295 and on the tip side of the nozzle 223 (the side of the reaction tube 210 for processing the substrate S). As described above, since the mixing portion 295 is provided at a position separated from the nozzle 223, the third gas and the fourth gas introduced into the nozzle 223 do not move to the mixing portion 295, and the third gas and the fourth gas are not mixed with the first gas and the second gas in the mixing portion 295. The distal end side of the gas holding portion 296 (the side of the reaction tube 210 for processing the substrate S) communicates with the third ejection port 223b via the third gas branch path 223a. With this arrangement, the third gas supplied through the nozzle 223 is ejected from the third ejection port 223b toward the substrate S supported by the substrate holder 300.

The mixed gas ejection port 225d and the third ejection port 223b are both provided on the end surface of the gas nozzle 220. Specifically, as shown in FIGS. 8B and 8C, on the end surface of the gas nozzle 220, the mixed gas ejection port 225d is formed in the vertical direction (that is, the direction perpendicular to the surface of the substrate S) which is the stacking direction of the substrate S. Hereinafter, this direction is simply referred to as a “vertical direction”.). On the other hand, the third ejection port 223b is provided on the upper side in the perpendicular direction. Thus, the mixed gas ejection port 225d ejects the mixed gas of the first gas and the second gas on the lower side in the perpendicular direction, and the third ejection port 223b ejects the third gas on the upper side in the perpendicular direction.

In such a gas nozzle 220, the nozzles 225a, 225b, the mixing portion 295, and the mixed gas ejection port 225d constitute a mixed gas supply flow path for supplying a mixed gas of the first gas and the second gas to the lower side in the vertical direction. The tip sides of the nozzles 225a, 225b are configured to be bent vertically downward in the vicinity of the mixing portion 295, so that a mixed gas supply flow path for supplying a mixed gas of the first gas and the second gas to the lower side in the vertical direction can be configured. In addition, the nozzle 223, the third gas branch path 223a, and the third ejection port 223b constitute a third gas supply flow path that supplies the third gas to the upper side in the perpendicular direction.

As illustrated in FIG. 8A, the third gas branch path 223a included in the third gas supply flow path is formed to branch the gas flow from the nozzle 223 into a plurality of (e.g., three) flows. With this arrangement, as illustrated in FIGS. 8B and 8C, a plurality of (e.g., three) the third ejection ports 223b are provided along the direction orthogonal to the perpendicular direction (this direction will be simply referred to as a “horizontal direction” hereinafter) (i.e., to be positioned side by side). All of the plurality of third ejection ports 223b have the same shape, and are formed in a circular shape, for example.

The mixed gas ejection port 225d is opened in the horizontal direction with respect to the substrate S, and for example, as shown in FIG. 8B, may be configured by one slit shape (horizontally elongated shape) in which the longitudinal direction extends in the horizontal direction. Furthermore, for example, as illustrated in FIG. 8C, it may be configured by a plurality of circular holes arranged in the horizontal direction.

### (3) Manufacturing Process of Semiconductor Device (Substrate Processing Step)

Next, a process of forming a thin film on the substrate S using the substrate processing apparatus 200 having the configuration described above will be described as one step of a semiconductor manufacturing process. In the following descriptions, the operation of each constituent included in the substrate processing apparatus is controlled by the controller 600.

Here, film forming processing for forming a film on the substrate S by alternately supplying the third gas, the first gas and the second gas will be described.

### (Transfer Chamber Pressure Adjustment Step)

Here, the pressure in the transfer chamber 217 is assumed to be the same level as that in a vacuum transfer chamber 140.

Specifically, an exhaust system (not illustrated) coupled to the transfer chamber 217 is operated to exhaust the atmosphere in the transfer chamber 217 so that the atmosphere in the transfer chamber 217 becomes a vacuum level.

The heater 282 may be operated in parallel with this step. Specifically, each of the heater 282a and the heater 282b may be operated. When the heater 282 is operated, it is operated at least during a film processing step 208 to be described later.

### (Substrate Loading Step)

When the transfer chamber 217 reaches the vacuum level, transfer of the substrates S is started. When the substrate S arrives at the vacuum transfer chamber 140, a gate valve (not illustrated) adjacent to the substrate loading port 149 is released, and the substrate S is loaded into the transfer chamber 217 from an adjacent vacuum transfer chamber (not illustrated).

At this time, the substrate holder 300 stands by in the transfer chamber 217, and the substrates S are transferred to the substrate holder 300. When a predetermined number of substrates S are transferred to the substrate holder 300, the vacuum transfer robot is retracted to a housing 141, and the substrate holder 300 is raised to move the substrates S into the reaction tube 210.

In the movement to the reaction tube 210, the surface of the substrate S is positioned to be aligned with the height of the division plate 226 and the division plate 232.

### (Heating Step)

When the substrates S are loaded into the reaction tube 210, the inside of the reaction tube 210 is controlled to have a predetermined pressure, and the heater 211 is controlled such that the processing temperature reaches a predetermined temperature.

### (Film Processing Step)

In the film processing step S208, the following steps a and b are sequentially executed.

[Step a]

In step a, the source gas as the fourth gas is supplied to the substrate S in the reaction tube 210.

Specifically, the valve 254 is opened to flow the fourth gas into the gas supply pipe 251. The flow rate of the fourth gas is adjusted by the MFC 253, and the fourth gas is supplied into the reaction tube 210 through the nozzle 223 and then exhausted. At this time, the fourth gas is supplied to the substrate S from the lateral side of the substrate S (fourth gas supply). At this time, the valves 268, 278 are opened to supply an inert gas into the reaction tube 210 via the nozzles 255a, 255b, respectively.

As processing conditions in this step,
processing temperature: 250 to 550° C., preferably 400 to 500° C.
processing pressure: 100 to 4000 Pa, preferably 100 to 1000 Pa
fourth gas supply flow rate: 0.1 to 3 slm
fourth gas supply time: 1 to 100 seconds, preferably 1 to 30 seconds
inert gas supply flow rate (per gas supply pipe): 0 to 10 slm is exemplified.

In addition, in the present specification, the expression of a numerical range such as “250 to 550° C.” means that a lower limit value and an upper limit value are included in the range. Therefore, for example, “250 to 550° C.” means “250° C. or more and 550° C. or less”. The same applies to other numerical ranges. In this specification, the processing temperature means the temperature of the substrate S or the temperature in the reaction tube 210, and the processing pressure means the pressure in the reaction tube 210. The gas supply flow rate: 0 slm means a case where the gas is not supplied. The same applies to the following description.

By supplying, for example, a chlorosilane-based gas to the substrate S as the fourth gas (source gas) under the above-described conditions, a Si-containing layer containing Cl is formed on an outermost surface of the substrate S serving as a base. The Si-containing layer containing Cl is formed on the outermost surface of the substrate S by physical adsorption or chemical adsorption of molecules of the chlorosilane-based gas, physical adsorption or chemical adsorption of molecules of a substance obtained by partially decomposing the chlorosilane-based gas, deposition of Si due to thermal decomposition of the chlorosilane-based gas, or the like. The Si-containing layer containing Cl may be an adsorption layer (physical adsorption layer or chemical adsorption layer) of molecules of the chlorosilane-based gas or molecules of a substance obtained by partially decomposing the chlorosilane-based gas, or may be a deposited layer of Si containing Cl. In the present specification, the Si-containing layer containing Cl is also simply referred to as an Si-containing layer.

In the present embodiment, when the fourth gas is supplied to the substrate S, by supplying the inert gas from the mixed gas ejection port 225d extending in the horizontal direction (arranged in the horizontal direction), it is possible to assist the fourth gas to spread laterally and to uniformly supply the fourth gas into the surface of the substrate S.

After the Si-containing layer is formed, the valve 254 is closed to stop the supply of the fourth gas into the reaction tube 210. Then, the inside of the reaction tube 210 is vacuum-exhausted to remove the gas and the like remaining in the reaction tube 210 from the inside of the reaction tube 210 (purge). At this time, the valves 268, 278 are kept open, and the inert gas is supplied into the reaction tube 210. The inert gas acts as a purge gas. As the inert gas, for example, a nitrogen (N₂) gas or a rare gas such as an argon (Ar) gas, a helium (He) gas, a neon (Ne) gas, or a xenon (Xe) gas is supplied. One or more of these gases can be used as the inert gas.

[Step b]

After step a is completed, the first gas and the second gas (reactant gas) are excited into a plasma state and supplied to the substrate S in the reaction tube 210, that is, the Si-containing layer formed on the substrate S.

Specifically, the valve 264, 274 is opened to allow the first gas and the second gas to flow respectively into the gas supply pipe 261, 271. The flow rates of the first gas and the second gas are adjusted by the MFCs 263, 273, and the first gas and the second gas are supplied into the reaction tube 210 through the nozzles 255a and 255b (supply first gas and second gas). At this time, the first gas and the second gas supplied into the reaction tube 210 are excited into a plasma state using a plasma generation unit (not illustrated). At this time, the valve 258 is opened, and the inert gas as the third gas is supplied into the reaction tube 210 through the nozzle 223.

As processing conditions in this step,
processing temperature: 200 to 900° C., preferably 300 to 850° C., more preferably 400 to 750°° C.
processing pressure: 13 to 400 Pa
first gas supply flow rate: 0.001 to 10 slm
first gas supply time: 10 to 600 seconds, preferably 1 to 50 seconds
second gas supply flow rate: 0.001 to 5 slm
second gas supply time: 10 to 600 seconds, preferably 1 to 50 seconds
inert gas supply flow rate (per gas supply pipe): 0 to 10 slm
RF power: 100 to 1000 W
RF frequency: 13.56 MHz or 27.12 MHZ
are exemplified.

Under the above-described conditions, at least a part of the Si-containing layer formed on the substrate S is oxidized (modified) by supplying, as the first gas, for example, a hydrogen-containing gas and as the second gas, for example, an oxygen-containing gas excited to a plasma state to the substrate S. As a result, a silicon oxide layer (SiO layer) is formed on the outermost surface of the substrate S serving as a base as a layer containing Si and O. When the SiO layer is formed, impurities such as Cl contained in the Si-containing layer form a gaseous substance containing at least Cl in the process of a modifying reaction of the Si-containing layer by the first gas and the second gas, and are discharged from the inside of the reaction tube 210. Accordingly, the SiO layer becomes a layer containing fewer impurities such as Cl than the Si-containing layer formed at step a. Here, as the first gas, for example, a hydrogen (H₂) gas, a deuterium (²H₂) gas, or the like can be used. One or more of these gases can be used as the first gas. As the second gas, for example, O₂ gas, ozone (O₃) gas, hydrogen peroxide (H₂O₂) gas, water vapor (H₂O) gas, or the like can be used. One or more of these gases can be used as the second gas.

As described above, the gas nozzle 220 is provided with the mixing portion 295 that mixes the first gas and the second gas introduced from each of the nozzle 225a and the nozzle 225b. Thus, before the first gas and the second gas reach the substrate S, it is possible to generate oxide film formation contributing molecules such as H radicals and O radicals in the mixing portion 295, and to secure a high film formation rate.

As described above, since the shape of the mixed gas ejection port 225d for ejecting the mixed gas of the first gas and the second gas is configured as a wide slit shape (horizontally long shape) in the horizontal direction or a plurality of round holes arranged in the horizontal direction, the mixed gas can be uniformly supplied into the surface of the substrate S.

When the treatment temperature is lower than 200° C., the production amount of H radicals or O radicals may be insufficient. By setting the treatment temperature to 200° C. or higher, a sufficient amount of H radicals and O radicals can be generated, and a SiO layer can be formed. By setting the treatment temperature to 300° C. or higher, the above-described effects can be reliably obtained. By setting the treatment temperature to 400° C. or higher, the above-described effect can be more reliably obtained.

When the treatment temperature exceeds 900° C., the temperature in the reaction tube 210 may incline to a high temperature, and ignition may occur. By setting the treatment temperature to 900° C. or lower, ignition can be suppressed. By setting the treatment temperature to 850° C. or lower, the above-described effects can be reliably obtained. By setting the treatment temperature to 750° C. or lower, the above-described effect can be more reliably obtained.

When the processing pressure is 13 Pa, the amount of H radicals or o radicals generated may be insufficient. By setting the processing pressure to 13 Pa or more, a sufficient amount of H radicals and O radicals can be generated, and a SiO layer can be formed.

When the processing pressure exceeds 400 Pa, the temperature in the reaction tube 210 may incline to a high temperature, and ignition may occur. When the processing pressure is 400 Pa or less, ignition can be suppressed.

In the present aspect, since the first gas and the second gas are mixed in the mixing portion 295 immediately before being supplied to the substrate S, even if the inside of the reaction tube 210 is at a high temperature and a high pressure, the residence time of the mixed gas can be shortened, so that ignition in the reaction tube 210 can be prevented.

When the supply flow rate ratio of the first gas to the second gas (flow rate of the second gas/flow rate of the first gas) is less than 0.2, the production amounts of H radicals and O radicals may be insufficient. By setting the ratio of the flow rate of the second gas to the flow rate of the first gas to 0.2 or more, a sufficient amount of H radicals and O radicals can be generated, and the SiO layer can be formed. By setting the ratio to 0.5 or more, the above-described effect can be reliably obtained. By setting the ratio to 1.0 or more, the above-described effect can be more reliably obtained.

When the ratio of the flow rate of the second gas to the flow rate of the first gas exceeds 30, the temperature in the reaction tube 210 may incline to a high temperature, and ignition may occur. By setting the ratio to 30 or less, it is possible to suppress ignition. By setting the ratio to 20 or less, the above-described effect can be reliably obtained. By setting the ratio to 10 or less, the above-described effect can be more reliably obtained.

After the SiO layer is formed, the valves 264, 274 are closed to stop the supply of the first gas and the second gas into the reaction tube 210. In addition, supply of RF power to an electrode (not illustrated) is stopped. Then, the gas and the like remaining in the reaction tube 210 are removed from the inside of the reaction tube 210 by processing procedures similar to the purge at step a (purge).

### [Cycle is Performed Predetermined Number of Times]

By performing a cycle in which steps a and b described above are executed non-simultaneously, that is, without synchronization, a predetermined number of times (n times, n is an integer of 1 or more), the surface of the substrate S can be used as a base, and a silicon oxide film (SiO film) having a predetermined thickness can be formed as a film of a predetermined thickness on the base, for example. The cycle described above is preferably repeated a plurality of times. That is, it is preferable to make the SiO layer formed per cycle thinner than a desired thickness of film and repeat the above-described cycle a plurality of times until the thickness of the SiO film formed by stacking the SiO layer becomes the desired thickness.

### (Substrate Unloading Step)

In this step, the processed substrates S are unloaded outward from the transfer chamber 217 in a reverse procedure to the substrate loading step described above.

While the formation of the horizontal gas flow has been described above, it is sufficient if the mainstream of the gas is formed in the horizontal direction as a whole, and the gas flow may be diffused in the vertical direction as long as the uniform processing of the plurality of substrates is not affected.

### (4) Effects of Embodiments

According to the present embodiment, one or a plurality of effects described below can be obtained.

(a) The plurality of gas nozzles 220 are disposed in a direction parallel to the surface of the substrate S, extend from the outside of the reaction tube 210 into the reaction tube 210, and include a nozzle 225a for introducing the first gas, a nozzle 225b for introducing the second gas, and a mixing portion 295 for mixing the first gas and the second gas. The mixed gas ejected from the plurality of gas nozzles 220 having such a configuration can be introduced in parallel to the surface of the substrate S. This makes it possible to suppress variations in the heating temperature of the mixed gas, to match the heating conditions, and to make the film forming process between the substrates uniform.

The mixed gas of the first gas and the second gas can be supplied to the substrate S by providing the mixing portion 295 for mixing the first gas and the second gas inside the gas nozzle 220 arranged in a direction parallel to the surface of the substrate S and configured to extend from the outside of the reaction tube 210 to the inside of the reaction tube 210. As described above, by supplying the mixed gas of the first gas and the second gas to the substrate S instead of mixing the first gas and the second gas on the substrate S, it is possible to generate oxide film formation contributing molecules such as H radicals and O radicals before reaching the substrate S, so that the film formation rate can be improved.

(b) Since the mixing portion 295 including the mixed gas ejection port 225d for ejecting the mixed gas of the first gas and the second gas is provided on the reaction tube 210 side for processing the substrate S, the residence time of the mixed gas in the reaction tube 210 can be shortened. As a result, even if the reaction tube 210 is heated to a high temperature and a high pressure, the occurrence of ignition can be prevented.

(c) Since the gas nozzle 220 includes the nozzle 223 that introduces an inert gas as the third gas, when the first gas and the second gas are supplied from the nozzles 225a, 225b, the inert gas is supplied from the nozzle 223, so that it is possible to prevent the first gas and the second gas from flowing back to the nozzle 223.

(d) Since the nozzle 223 is disposed between the nozzle 225a and the nozzle 225b, for example, when the source gas is supplied as the fourth gas from the nozzle 223, supplying the inert gas from the nozzles 225a and 225b can assist the fourth gas to be widely supplied in the left-right direction.

(e) Since the mixing portion 295 is provided at a position separated from the nozzle 223, the third gas and the fourth gas introduced into the nozzle 223 do not move to the mixing portion 295, and it is possible to prevent the third gas and the fourth gas from being mixed with the first gas and the second gas in the mixing portion 295.

(f) Since the mixed gas ejection port 225d is opened in the horizontal direction with respect to the substrate S and is configured by one slit shape (horizontally long shape) whose longitudinal direction extends in the horizontal direction or a plurality of holes arranged in the horizontal direction, a film can be uniformly formed in the surface of the substrate S without generating a vortex.

(g) The gas nozzles 220 are provided in the accommodating portion 290 in multiple stages in the stacking direction of the plurality of substrates S, whereby the gas supply with respect to each of the plurality of substrates S may be individually performed, and the in-plane uniform processing may be performed on any of the plurality of substrates S.

### Other Embodiments of Present Disclosure

The embodiments of the present disclosure have been specifically described above. However, the present disclosure is not limited to the above embodiments, and various modifications can be made without departing from the gist thereof.

In the above-described embodiment, a case where the mixed gas ejection port 225d has a slit shape or a plurality of circular holes arranged in the horizontal direction has been described as an example, but the present disclosure is not limited thereto. For example, the mixed gas ejection port 225d may be formed by arranging a plurality of holes formed in a triangular shape or a polygonal shape in the horizontal direction.

While the case where a film is formed on the substrate S using the first gas, the second gas, and the fourth gas in the film forming process performed by the substrate processing apparatus has been exemplified in the embodiments described above, the present disclosure is not limited thereto. That is, another type of thin film may be formed using another type of gas as the processing gas used for the film forming processing.

While the HCDS gas has been exemplified as the fourth gas in the embodiments described above, the first gas is not limited thereto as long as it contains silicon and has a Si-Si bond, and for example, tetrachlorodimethyldisilane ((CH₃)₂Si₂Cl₄, abbreviation: TCDMDS) or dichlorotetramethyldisilane ((CH₃)₄Si₂Cl₂, abbreviation: DCTMDS) may be used.

In the above aspect, the reaction state of the mixed gas can be changed by changing the volume of the mixing portion 295 of the mixed gas of the first gas and the second gas, so that a desired mixed gas can be supplied relatively easily.

While the film forming process has been exemplified as a process performed by the substrate processing apparatus in the embodiments described above, the present disclosure is not limited thereto. That is, the present disclosure may be applied to a case of performing another substrate process, such as an annealing process, a diffusion process, oxidizing, nitriding, or a lithography process, in addition to the film forming process as long as the process is performed by supplying gas to the substrate to be processed. Furthermore, the present disclosure may also be applied to another substrate processing apparatus, such as an annealing processing apparatus, an etching apparatus, an oxidizing apparatus, a nitriding apparatus, an exposure apparatus, a coating apparatus, a drying apparatus, a heating apparatus, or a processing apparatus using plasma. Those apparatuses may be mixed in the present disclosure. Part of the constituents in the embodiments described above can be given another constituent, can be deleted, or can be replaced with another constituent.

Preferably, the recipe used in each processing is individually prepared according to processing contents and stored in the memory 603 through an electric communication line or the external memory 682. Then, when each piece of processing is started, it is preferable that the CPU 601 appropriately selects an appropriate recipe among the plurality of recipes stored in the memory 603 according to a processing content. As a result, it is possible to form films with various film types, composition ratios, film qualities, and film thicknesses with excellent reproducibility with one substrate processing apparatus. It is possible to reduce a burden on an operator, and it is possible to quickly start each processing while avoiding an operation error.

Such a recipe as described above is not limited to a newly created recipe and thus may be prepared, for example, due to a change in an existing recipe installed in advance on the substrate processing apparatus. In a case where a change is made in a recipe, the changed recipe may be installed onto the substrate processing apparatus through a telecommunication line or a recording medium on which the recipe is recorded. In addition, the inputter/outputter 122 in the existing substrate processing apparatus may be operated to directly make a change in an existing recipe installed in advance on the substrate processing apparatus.

In the above-described various aspects and various modified examples, an example of forming a film using a batch type substrate processing apparatus that processes a plurality of substrates at a time has been described. The present disclosure is not limited to the above-described various aspects and various modified examples, and can be appropriately applied to, for example, a case of forming a film using a single wafer type substrate processing apparatus that processes one or more substrates at a time. In addition, in the above-described various aspects and various modified examples, an example of forming a film using a substrate processing apparatus having a hot wall type process furnace has been described. The present disclosure is not limited to the above-described various aspects and various modified examples, and can also be appropriately applied to a case of forming a film using a substrate processing apparatus having a cold wall type process furnace.

Even when these substrate processing apparatuses are used, it is possible to perform each processing under the same processing procedure and processing conditions as the processing procedure and processing conditions in the above-described various aspects and various modified examples. Therefore, it is possible to obtain the same effects as in the above-described various aspects and various modified examples.

The above-described various aspects and various modified examples can be appropriately combined and used. For example, the processing procedures and processing conditions at that time can be made similar to the processing procedures and processing conditions in the above-described various aspects and various modified examples.

According to the present disclosure, film formation processing between substrates can be uniformly performed.

What is claimed is:

1. A substrate processing apparatus comprising:
a processing chamber that accommodates a substrate holder holding a plurality of substrates;
a plurality of gas suppliers that are disposed in a direction parallel to a surface of the substrate, extend from an outside to an inside of the processing chamber, and each include a first gas introduction portion that introduces a first gas, a second gas introduction portion that introduces a second gas, and a mixing portion that mixes the first gas with the second gas; and
an accommodating portion that is disposed to extend in the direction parallel to the surface of the substrate on a lateral side of the processing chamber and accommodates the plurality of gas suppliers.

2. The substrate processing apparatus according to claim 1, wherein the mixing portion is provided on a side of the processing chamber where the substrate is processed.

3. The substrate processing apparatus according to claim 1, wherein the gas supplier comprises a third gas introduction portion that introduces a third gas.

4. The substrate processing apparatus according to claim 3, wherein the third gas introduction portion is disposed between the first gas introduction portion and the second gas introduction portion.

5. The substrate processing apparatus according to claim 3, wherein the mixing portion is provided at a position separated from the third gas introduction portion.

6. The substrate processing apparatus according to claim 1, wherein the gas supplier includes a mixed gas ejection port that supplies the gas mixed in the mixing portion.

7. The substrate processing apparatus according to claim 6, wherein the mixed gas ejection port is opened in a horizontal direction with respect to the substrate.

8. The substrate processing apparatus according to claim 6, wherein the mixed gas ejection port is composed of a plurality of holes.

9. The substrate processing apparatus according to claim 6, wherein the mixed gas ejection port is formed in a slit shape.

10. The substrate processing apparatus according to claim 1, wherein
the first gas is a hydrogen-containing gas, and
the second gas is an oxygen-containing gas.

11. The substrate processing apparatus according to claim 3, wherein the third gas is an inert gas.

12. The substrate processing apparatus according to claim 3, wherein a fourth gas different from the third gas can be supplied to the third gas introduction portion.

13. The substrate processing apparatus according to claim 12, wherein an inert gas can be supplied to the first gas introduction portion and the second gas introduction portion when the fourth gas is supplied.

14. The substrate processing apparatus according to claim 1, wherein the processing chamber accommodates a substrate holder on which the plurality of substrates are loaded and held.

15. The substrate processing apparatus according to claim 14, wherein the gas supplier is accommodated in the accommodating portion in multiple stages in a direction of loading the substrate.

16. The substrate processing apparatus according to claim 12, wherein the plurality of gas suppliers are configured to be inserted into the accommodating portion so as to enable supply of a mixed gas obtained by mixing the first gas and the second gas to each of the plurality of substrates from the direction parallel to the surface of the substrate in accordance with an interval in an up-down direction of the plurality of substrates, and extend from an outside to an inside of a reaction tube.

17. A gas supply structure disposed in a direction parallel to a surface of a substrate, extending from an outside to an inside of a processing chamber where the substrate is processed, and comprising a first gas introduction portion that introduces a first gas, a second gas introduction portion that introduces a second gas, and a mixing portion that mixes the first gas with the second gas.

18. A method of processing a substrate comprising:
accommodating a substrate holder in a processing chamber of a substrate processing apparatus comprising the processing chamber that accommodates the substrate holder on which a plurality of substrates are loaded and held, a plurality of gas suppliers that are disposed in a direction parallel to a surface of each of the substrates, extend from an outside to an inside of the processing chamber, and each include a first gas introduction portion that introduces a first gas, a second gas introduction portion that introduces a second gas, and a mixing portion that mixes the first gas with the second gas, and an accommodating portion that is disposed to extend in the direction parallel to the surface of the substrate on a lateral side of the processing chamber and accommodates the plurality of gas suppliers; and
mixing the first gas and the second gas and supplying to the plurality of substrates.

19. A method of manufacturing a semiconductor device, using the method of processing a substrate according to claim 18.

20. A computer-readable recording medium storing a program that causes a computer to make a substrate processing apparatus perform a process comprising the method of processing a substrate according to claim 18.
